(19) United States
(12) Patent Application Publication
(10) Pub. No.: US 2026/0107574 A1
(43) Pub. Date: Apr. 16, 2026

(54) MULTI-STACK SEMICONDUCTOR DEVICE INCLUDING CHANNEL STRUCTURES HAVING DIFFERENT CHANNEL WIDTHS

(71) Applicant: SAMSUNG ELECTRONICS CO., LTD., Suwon-si (KR)

(72) Inventors: Beomjin PARK, Halfmoon, NY (US); Edward Namkyu CHO, Slingerlands, NY (US); Hyo Jong SHIN, Mechanicville, NY (US); Jinyoung LIM, Schenectady, NY (US); Kang-ill SEO, Springfield, VA (US)

(73) Assignee: SAMSUNG ELECTRONICS CO., LTD., Suwon-si (KR)

(21) Appl. No.: 19/276,824

(22) Filed: Jul. 22, 2025

Related U.S. Application Data
(60) Provisional application No. 63/707,473, filed on Oct. 15, 2024.

(51) Int. Cl. H10D 84/90; H10D 89/10

(52) U.S. Cl. CPC H10D 84/924; H10D 84/953; H10D 89/10

(57) ABSTRACT

A multi-stack semiconductor device includes: a 1^{st} active pattern extending in a 1^{st} direction; a 2^{nd} active pattern extending in the 1^{st} direction, the 2^{nd} active pattern being above the 1^{st} active pattern in a 3^{rd} direction which intersects the 1^{st} direction and a 2^{nd} direction intersecting the 1^{st} direction; and a plurality of gate structures extending in the 2^{nd} direction and arranged in the 1^{st} direction, wherein at least one of the 1^{st} active pattern and the 2^{nd} active pattern has a width in the 2^{nd} direction which varies along the 1^{st} direction.

### CROSS-REFERENCE TO THE RELATED APPLICATION

This application is based on and claims priority from U.S. Provisional Application No. 63/707,473 filed on Oct. 15, 2024 in the U.S. Patent and Trademark Office, the disclosure of which is incorporated herein in its entirety by reference.

### BACKGROUND

### 1. Field

Apparatuses and methods consistent with example embodiments of the inventive concept relate to a multi-stack semiconductor device in which channel widths of transistor structures are different.

### 2. Description of the Related Art

Increasing demand for high-performance, high-density semiconductor devices has introduced a nanosheet transistor characterized by multiple nanosheet layers bridging source/drain regions formed at both ends thereof and a gate structure that wraps around or surround all four sides of the nanosheet layers. These nanosheet layers serve as a channel structure for current flow between the source/drain regions of the nanosheet transistor. Due to this structure, improved control of current flow through the nanosheet layers by the gate structure is enabled in addition to high-device density in a semiconductor device including the nanosheet transistor. The nanosheet transistor is also referred to as various different names such as gate-all-around transistor, multi-bridge channel field-effect transistor (MBCFET), nanobeam transistor, nanoribbon transistor, superimposed channel device, etc.

A multi-stack semiconductor device or a three-dimensional stacked semiconductor device has been implemented by stacking one nanosheet transistor structure on another one or more nanosheet transistor structures, for example, to achieve a higher-density complementary metal-oxide semiconductor (CMOS) device in which a p-type or n-type field-effect transistor (PFET or NFET), which may be a nanosheet transistor, is formed at a 1^{st} level and another PFET or NFET, which may be another nanosheet transistor, is stacked at a 2^{nd} level vertically above the 1^{st} level. However, the inventors of the present application have learned that there are many challenges to overcome in simply stacking FET structures to achieve a multi-stack semiconductor device required in the field for practical use.

Thus, the inventors have designed and developed a multi-stack semiconductor device described herein.

Information disclosed in this Background section has already been known to the inventors before achieving the embodiments of the present application or is technical information acquired in the process of achieving the embodiments. Therefore, it may contain information that does not form the prior art that is already known to the public.

### SUMMARY

The disclosure provides a multi-stack semiconductor device in which a 1^{st} active pattern forming a plurality of 1^{st} field-effect transistors and a 2^{nd} active pattern, vertically above the 1^{st} active pattern, forming a plurality of 2^{nd} field-effect transistors have widths respectively and independently varying along a channel-length direction, by which the multi-stack semiconductor device may be able to form a plurality of different circuits having different device functions or performances.

According to one or more embodiments, there is provided a multi-stack semiconductor device which may include: a 1^{st} active pattern extending in a 1^{st} direction; a 2^{nd} active pattern extending in the 1^{st} direction, the 2^{nd} active pattern being above the 1^{st} active pattern in a 3^{rd} direction which intersects the 1^{st} direction and a 2^{nd} direction intersecting the 1^{st} direction; and a plurality of gate structures extending in the 2^{nd} direction and arranged in the 1^{st} direction. Here, at least one of the 1^{st} active pattern and the 2^{nd} active pattern may have a width in the 2^{nd} direction which varies along the 1^{st} direction.

According to one or more embodiments, there is provided a multi-stack semiconductor device which may include: a 1^{st} channel structure comprising 1^{st} channel layers arranged in a 3^{rd} direction intersecting a 1^{st} direction and a 2^{nd} direction; and a 2^{nd} channel structures above the 1^{st} channel structure, the 2^{nd} channel structure comprising 2^{nd} channel layers arranged in the 3^{rd} direction. Here, the 2^{nd} channel structure may have a smaller width than the 1^{st} channel structure in the 2^{nd} direction, and a number of the 1^{st} channel layers may be greater than a number of the 2^{nd} channel layers.

According to embodiments, there is provided a multi-stack semiconductor device which may include: a 1^{st} channel structure; and a 2^{nd} channel structure above the 1^{st} channel structure in a 3^{rd} direction intersecting a 1^{st} direction and a 2^{nd} direction. Here, the 1^{st} channel structure may have a greater height than the 2^{nd} channel structure.

### BRIEF DESCRIPTION OF THE DRAWINGS

Example embodiments of the inventive concept will be more clearly understood from the following detailed description taken in conjunction with the accompanying drawings in which:

FIGS. 1A and 1B illustrate a multi-stack semiconductor device in which a plurality of 1^{st} field-effect transistors (FETs) at a 1^{st} level have a same channel width and a plurality of 2^{nd} FETs at a 2^{nd} level also have a same channel width, different from the channel width of the 1^{st} FETs, according to one or more embodiments;

FIGS. 2A-2F illustrate a multi-stack semiconductor device in which a plurality of 1^{st} FETs at a 1^{st} level have varying channel widths and a plurality of 2^{nd} FETs at a 2^{nd} level also have varying channel widths, different from the varying widths of the 1^{st} FETs, the 1^{st} FET having more channel layers than the 2^{nd} FET, according to one or more embodiments;

FIGS. 3A-3F illustrate a multi-stack semiconductor device in which a plurality of 1^{st} FETs at a 1^{st} level have varying channel widths and a plurality of 2^{nd} FETs at a 2^{nd} level also have varying channel widths, different from the varying channel widths of the 1^{st} FETs, the 1^{st} FET having less channel layers than the 2^{nd} FET, according to one or more other embodiments; and

FIG. 4 is a schematic block diagram illustrating an electronic device including one or more multi-stack FETs including a plurality of different channel widths, according to one or more embodiments.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, channel layers, sacrificial layers, and isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures.

For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element may be a “right” element and a “left” element when a device or structure including these elements are differently oriented.

It will be understood that, although the terms “1^{st},” “2^{nd},” “3^{rd},” “4^{th},” “5^{th},” “6^{th},” etc. may be used herein to describe various elements, these elements should not be limited by these terms. These terms are only used to distinguish one element from another element. Thus, a 1^{st} element described in the descriptions of an embodiments could be termed a 2^{nd} element in the descriptions of another element or one or more claims, and vice versa without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c.

Herein, the terms of degree including “substantially” or “about” may be used. In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X. Still, when a term “same” is used to compare parameters of two or more elements, the term may cover “substantially same”parameters.

It will be understood that, when the term “contact” is used to describe two metal elements, for example, a metal line and a via structure, a barrier metal layer such including titanium (Ti), tantalum (Ta), titanium nitride (TiN), tantalum nitride (TaN), tungsten nitride (WN), nickel nitride (NiN), cobalt nitride (CoN), or platinum nitride (PtN), not being limited thereto, may be formed therebetween. Further, it will be understood that, when a metal contract structure is described as being formed on or contact a surface of a source/drain region, a silicide layer including cobalt silicide (CoSi₂), nickel silicide (NiSi₂), titanium silicide (TiSi₂), or tungsten silicide (WSi₂), not being limited thereto, may be formed therebetween.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers of semiconductor devices including a nanosheet transistor and materials forming the same may or may not be described in detail herein. For example, a certain isolation layer or structure of a semiconductor device and materials forming the same may be omitted herein when this layer or structure is not related to the novel features of the embodiments. Also, descriptions of materials forming well-known structural elements of a semiconductor device may be omitted herein when those materials are not relevant to the novel features of the embodiments. Herein, the term “isolation” and “insulation” pertains to electrical insulation or separation between structures, layers, components or regions in a corresponding device or structure.

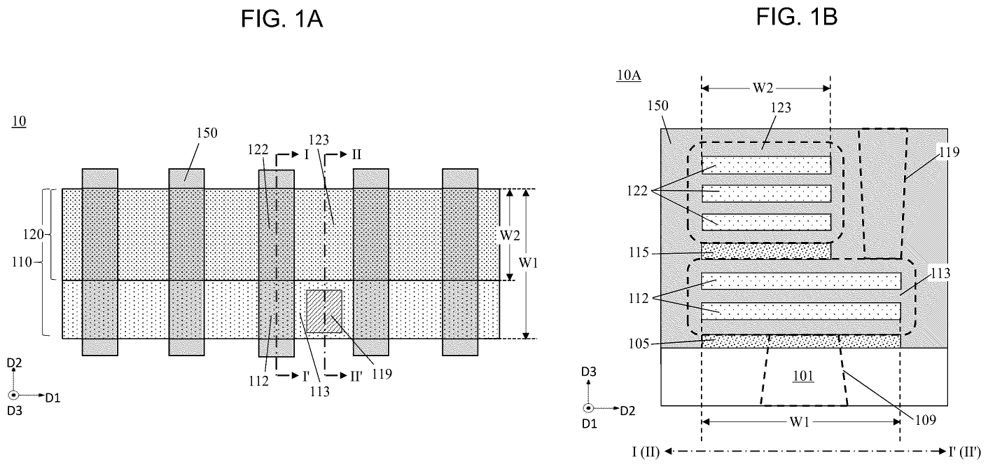

FIGS. 1A and 1B illustrate a multi-stack semiconductor device in which a plurality of 1^{st} field-effect transistors (FETs) at a 1^{st} level have a same channel width and a plurality of 2^{nd} FETs at a 2^{nd} level also have a same channel width, different from the channel width of the 1^{st} FETs, according to one or more embodiments.

FIG. 1A is a plan view of a multi-stack semiconductor device 10, and FIG. 1B is a cross-section view of the multi-stack semiconductor device 10 taken along a line I-I′ shown in FIG. 1A. In order to assist better understanding of the multi-stack semiconductor device 10 of FIG. 1A, FIG. 1B also shows source/drain regions and contact plugs that can be seen at a cross-section view taken along a line II-II′ using dashed lines.

It is to be understood that FIGS. 1A and 1B show only selected elements formed on a front side of the multi-stack semiconductor device such as front-end-of-line (FEOL) structures including channel structures, source/drain regions and gate structures, and thus, some structural elements such as back-end-of-line (BEOL) structures and middle-of-line (MOL) structures are not shown for brevity purposes.

Referring to FIGS. 1A and 1B, the multi-stack semiconductor device 10 may include a 1^{st} active pattern 110 and a 2^{nd} active pattern 120 extending in a D1 direction. The 2^{nd} active pattern 120 may be stacked on the 1^{st} active pattern 110 formed on a backside isolation structure 101 in a D3 direction intersecting the D1 direction and a D2 direction, and may partially overlap the 1^{st} active pattern 110 in the D3 direction. The 1^{st} active pattern 110 may have a width W1 which is greater than a width W2 of the 2^{nd} active pattern 120 in the D2 direction. The widths W1 and W2 may be uniform or consistent along the D1 direction. In the multi-stack semiconductor device 10 may also be formed of a plurality of gate structures 150 arranged in the D1 direction and extending in the D2 direction across the active patterns 110 and 120.

The D1 direction refers to a channel-length direction in which a current flows between two source/drain regions connected to each other through a channel structure, the D2 direction refers to a channel-width direction or a cell-height direction, and the D3 direction refers to a channel-thickness direction. In addition, the D1 direction and the D2 direction may each be referred to as a horizontal direction and the D3 direction may be referred to as a vertical direction.

The multi-stack semiconductor device 10 may include a multi-stack FET 10A formed of a 1^{st} FET, which is an NFET or PFET at a 1^{st} level, and a 2^{nd} FET, which is also an NFET or PFET at a 2^{nd} level above the 1^{st} level in the D3 direction. The 1^{st} FET and the 2^{nd} FET may be formed based on the 1^{st} active pattern 110 and the 2^{nd} active pattern 120, respectively, along with a corresponding gate structure 150.

The 1^{st} active pattern 110 for the 1^{st} FET may form a 1^{st} channel structure 112 and 1^{st} source/drain regions 113 at the 1^{st} level. The 1^{st} channel structure 112 may be formed of a plurality of 1^{st} channel layers, which are nanosheet layers, epitaxially grown from a substrate therebelow to form the 1^{st} FET as a nanosheet transistor. The substrate may have been replaced by the backside isolation structure 101 in a process of manufacturing the multi-stack semiconductor device 10 to form a backside power delivery network (BSPDN). The 1^{st} channel structure 112 may have the width W1. The substrate may have been a silicon (Si) substrate although it may have included other materials such as silicon germanium (SiGe), silicon carbide (SiC), not being limited thereto, and the 1^{st} channel layers forming the 1^{st} channel structure 112 may also be formed to include silicon (Si) and may have the width W1.

The 2^{nd} active pattern 120 for the 2^{nd} FET may form a 2^{nd} channel structure 122 and 2^{nd} source/drain regions 123 at the 2^{nd} level. The 2^{nd} channel structure 122 may be formed of a plurality of 2^{nd} channel layers, which are nanosheet layers, also epitaxially grown from the substrate to form the 2^{nd} FET as another nanosheet transistor. The 2^{nd} channel layers forming the 2^{nd} channel structure 122 may also be formed to include silicon (Si), and may have the width W2.

The 1^{st} source/drain regions 113 may be epitaxially grown from the 1^{st} channel layers of the 1^{st} channel structure 112, and the 2^{nd} source/drain regions 123 may be epitaxially grown from the 2^{nd} channel layers of the 2^{nd} channel structure 122. In a case where the 1^{st} source/drain regions 113 or the 2^{nd} source/drain regions 123 are of n-type, the source/drain regions may be formed of silicon (Si) doped with n-type impurities (e.g., phosphorus (P), arsenic (As), or antimony (Sb)). In contrast, in a case where the 1^{st} source/drain regions 113 or the 2^{nd} source/drain regions 123 are of p-type, the source/drain regions may be formed of silicon germanium (SiGe) doped with p-type impurities (e.g., boron (B), gallium (Ga), or indium (In)).

The 1^{st} channel structure 112 may be surrounded by a gate structure 150 which controls current flow between the 1^{st} source/drain regions 113 through the 1^{st} channel structure 112. The 2^{nd} channel structure 122 may also be surrounded by the gate structure 150 which controls current flow between the 2^{nd} source/drain regions 123 through the 2^{nd} channel structure 122.

The gate structure 150 may include a gate dielectric layer formed on or surrounding the 1^{st} channel layers, a 1^{st} work-function metal layer formed on or surrounding this gate dielectric layer, and a gate-fill metal formed on or surrounding the 1^{st} work-function metal layer. The 1^{st} work-function metal layer and the gate-fill metal may be collectively referred to as a 1^{st} gate electrode. The gate dielectric layer may be configured to electrostatically control channel conductivity while blocking current flow between the 1^{st} gate electrode and the 1^{st} channel structure 112. The 1^{st} work-function metal layer may control a gate threshold voltage of the 1^{st} FET of the multi-stack FET 10A, and the gate-fill metal may be configured to receive a gate input signal for the multi-stack FET 10A. The gate structure 150 along with the 1^{st} channel structure 112 and the 1^{st} source/drain regions 113 may form the 1^{st} FET as an NFET or a PFET at the 1^{st} level.

The gate dielectric layer formed on or surrounding the 1^{st} channel structure 112 may extend to also be formed on or surround the 2^{nd} channel layers. A 2^{nd} work-function metal layer may be formed on or surround this gate dielectric layer on the 2^{nd} channel layers. The gate-fill metal formed on or surrounding the 1^{st} work-function metal layer may also extend to be formed on or surround the 2^{nd} work-function metal layer. The 2^{nd} work-function metal layer and the gate-fill metal may be collectively referred to as a 2^{nd} gate electrode. The gate dielectric layer may be configured to electrostatically control channel conductivity while blocking current flow between the 2^{nd} gate electrode and the 2^{nd} channel structure 122, and the 2^{nd} work-function metal layer may control a gate threshold voltage of the 2^{nd} FET of the multi-stack FET 10A. Thus, the 2^{nd} channel structure 122, the 2^{nd} source/drain regions 123 and the gate structure 150 may form the 2^{nd} FET as a PFET or an NFET at the 2^{nd} level.

The multi-stack FET 10A may include a bottom diffusion isolation (BDI) layer 105 between the 1^{st} source/drain regions 113 and the backside isolation structure 101 which is formed to suppress current leakage from the 1^{st} source/drain regions 113 or the 1^{st} channel structure 112 to the substrate or the backside isolation structure 101 therebelow. The BDI layer 105 may be formed of an insulation material or a dielectric material such as SiBCN, SiCN, SiOC, SiOCN, Si₃N₄, etc. The multi-stack FET 10A may also include a middle isolation layer 115 between the 1^{st} channel structure 112 including the 1^{st} channel layers and the 2^{nd} channel structure 122 including the 2^{nd} channel layers to isolate these two channel structures. The middle isolation layer 115 may be formed of an insulation material or a dielectric material such as SiBCN, SiCN, SiOC, SiOCN, Si₃N₄, etc. which may be the same as or different from the materials forming the BDI layer 105.

As described earlier, the 2^{nd} active pattern 120 has the width W2 which is smaller than the width W1 of the 1^{st} active pattern 110 in the D2 direction. Accordingly, the 2^{nd} channel layers forming the 2^{nd} channel structure 122 of the 2^{nd} FET may have the width W2 which is smaller than the width W1 of the 1^{st} channel layers forming the 1^{st} channel structure 112 of the 1^{st} FET in the D2 direction, and the 2^{nd} channel structure 122 may partially overlap the 1^{st} channel structure 112 in the D3 direction.

For example, left side surfaces of the 2^{nd} channel layers may be aligned or coplanar with left side surfaces of the 1^{st} channel layers in the D3 direction, while right side surfaces of the 2^{nd} channel layers are not aligned or coplanar with right side surfaces of the 1^{st} channel layers in the D3 direction. Thus, the 2^{nd} source/drain regions 123 epitaxially grown from the 2^{nd} channel layers may also be formed to have a smaller width than the 1^{st} source/drain regions 113 epitaxially grown from the 1^{st} channel layers in the D2 direction. Accordingly, a right side surface of the 1^{st} source/drain region 113 may not be overlapped by the 2^{nd} source/drain region 123, while a left side surface of a 1^{st} source/drain region 113 may be overlapped by the 2^{nd} source/drain region 123, in the D3 direction.

The width difference between the source/drain regions 113 and 123 may provide a free space above a top surface of the 1^{st} source/drain region 113 which is not vertically overlapped by the 2^{nd} source/drain region 123 so that other circuit elements such as a frontside contact structure 119 may be vertically formed straight through this space to contact at least a portion of the top surface of the 1^{st} source/drain region 113.

Alternatively or additionally, a backside contact structure 109 may be formed to contact a bottom surface of the 1^{st} source/drain region 113. To form the backside contact structure 109 of metal or metal alloy, the substrate may have been replaced by the backside isolation structure 101 formed of a low-k dielectric material such as silicon oxide (SiO₂), not being limited thereto. The backside contact structure 109 along with one or more backside metal lines formed therebelow may form the BSPDN of the multi-stack semiconductor device 10.

The foregoing structural characteristics of the channel structures 112, 122 and the source/drain regions 113, 123 may be provided to address increasing demands for a high device density and an improved device performance in a multi-stack semiconductor device. For example, as the frontside contact structure 119 can be formed on the top surface of the 1^{st} source/drain region 113 through the non-overlapped free space, the multi-stack semiconductor device 10 including the multi-stack FET 10A may achieve an area gain and reduced contact resistance compared to a multi-stack semiconductor device in which a frontside contact structure is formed on a side surface or a bottom surface of a lower source/drain region (corresponding to the 1^{st} source/drain region 113) when the lower source/drain region and an upper source/drain region (corresponding to the 2^{nd} source/drain region 123) have a same width in the D2 direction.

In the multi-stack FET 10A, the 2^{nd} channel structure 122 forming the 2^{nd} FET may have a greater number of channel layers than that of the 1^{st} channel structure 112 forming the 1^{st} FET such that the two FETs may have a same or substantially same effective channel width (W_{eff}) in a case where the channel layers have a same thickness in the D3 direction and a same length in the D1 direction. For example, as shown in FIG. 1B, the 2^{nd} channel structure 122 may have three (3) channel layers while the 1^{st} channel structure 112 have two (2) channel layers. By configuring the number of channel layers for the 1^{st} channel structure 112 and the 2^{nd} channel structure 122, the 1^{st} FET and the 2^{nd} FET may be formed to have a same or substantially same DC performance. In a case where the 1^{st} channel structure 112 and the 2^{nd} channel structures 122 have the same effective channel width, the 1^{st} source/drain region 113 and the 2^{nd} source/drain region 123 epitaxially grown from the 1^{st} channel structure 112 and the 2^{nd} channel structures 122, respectively, may have a same area.

The different channel widths and the different number of channel layers may facilitate optimization of the multi-stack semiconductor device 10 in terms of not only area gain for a high-density semiconductor device but also a device performance such as current speed, work load distribution, power efficiency, contact resistance, capacitance, thermal control, structural stability, etc.

However, referring back to FIG. 1A, as the 1^{st} active pattern 110 and the 2nd active pattern 120 may have the uniform, consistent widths W1 and W2, respectively, along the D1 direction. Thus, a plurality of 1^{st} FETs formed based on the 1^{st} active pattern 110 may have the same channel widths W1 and the same source/drain region width, and a plurality of 2^{nd} FETs formed based on the 2^{nd} active pattern 120 may also have the same channel width W2 and the same source/drain region width. Thus, the multi-stack semiconductor device 10 may not allow formation of a plurality of different logic circuits having different design requirements.

Provided herebelow are multi-stack semiconductor devices formed to address the foregoing circuit design restriction.

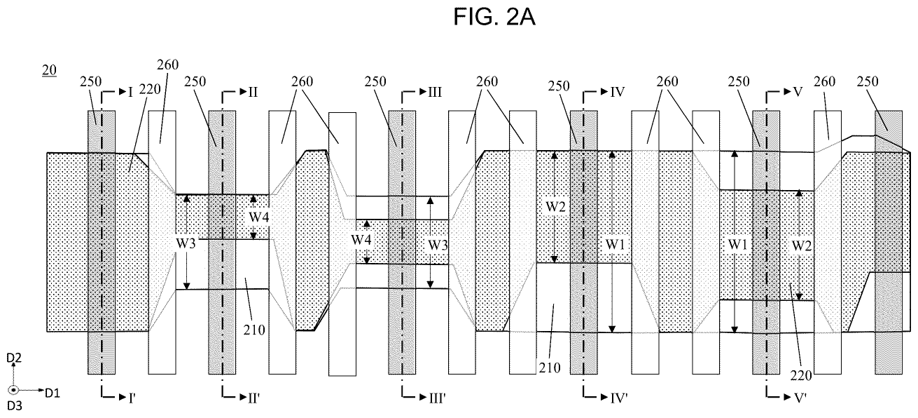

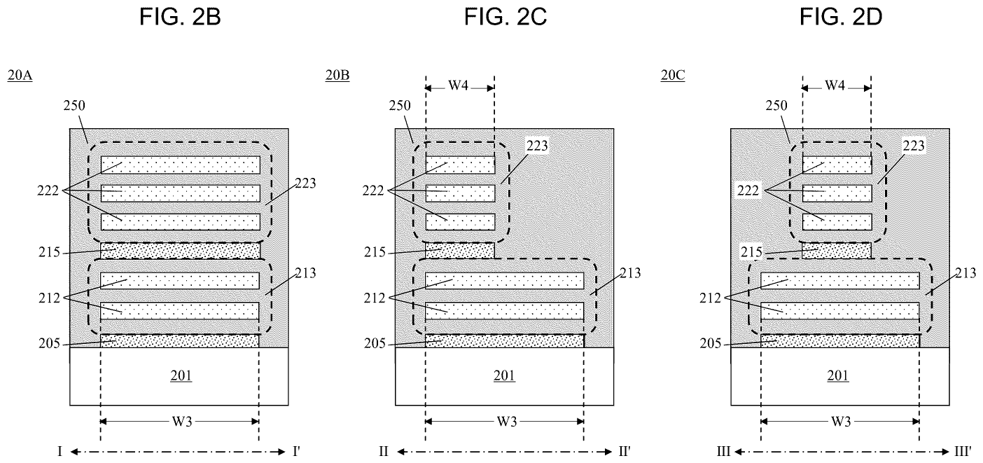

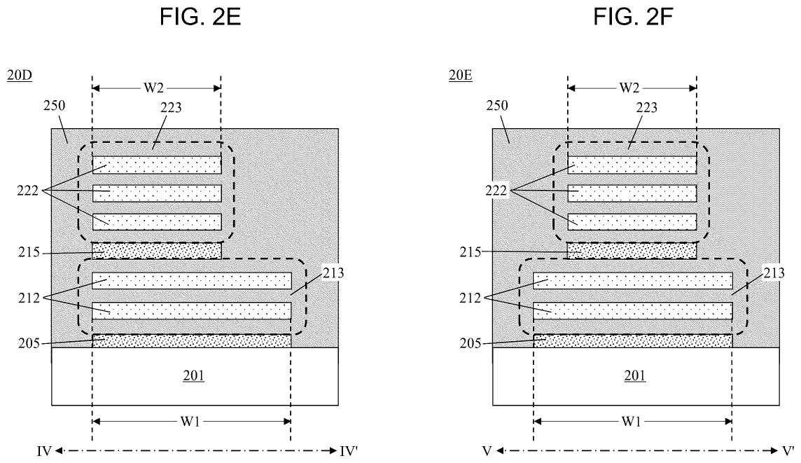

FIGS. 2A-2F illustrate a multi-stack semiconductor device in which a plurality of 1^{st} FETs at a 1^{st} level has varying channel widths and a plurality of 2^{nd} FETs at a 2^{nd} level also has varying channel widths, different from the varying widths of the 1^{st} FETs, the 1^{st} FET having more channel layers than the 2^{nd} FET, according to one or more embodiments.

FIG. 2A is a plan view of a multi-stack semiconductor device 20, and FIG. 2B-2F are cross-section views of the multi-stack semiconductor device 20 taken along lines I-I′, II-II′, III-III', IV-IV′ and V-V′ shown in FIG. 2A. In order to assist better understanding of the multi-stack semiconductor device 20 of FIG. 2A, FIGS, 2B-2F also show source/drain regions that can be seen at different cross-section views using dashed lines.

Referring to FIG. 2A, like the multi-stack semiconductor device 10 of FIG. 1A, the multi-stack semiconductor device 20 may also include a 1^{st} active pattern 210 and a 2^{nd} active pattern 220 extending in the D1 direction while the 2^{nd} active pattern 220 is stacked on the 1^{st} active pattern 210 formed on a backside isolation structure 201 in the D3 direction. Also, like in the multi-stack semiconductor device 10, a plurality of gate structures 250 may be arranged in the D1 direction and may extend in the D2 direction across the active patterns 210 and 220.

Further, a plurality of channel structures and source/drain regions may also be formed based on the active patterns 210 and 220 in the multi-stack semiconductor device 20 to form a plurality of multi-stack FETs each including a 1^{st} FET at the 1^{st} level and a 2^{nd} FET at the 2^{nd} level as in the multi-stack semiconductor device 10. In addition, like in the multi-stack semiconductor device 10, the 1^{st} FETs may each have more channel layers than the 2^{nd} FETs, and the 1^{st} FETs may each be an NFET while the 2^{nd} FETs may each be a PFET. In this regard, duplicate descriptions about these channel structures, source/drain regions and gate structures for the 1^{st} and 2^{nd} FETs in terms of their functions and materials may be omitted, and instead, different aspects of the multi-stack semiconductor device 20 may be described herebelow.

An aspect of the multi-stack semiconductor device 20 is that at least one of the 1^{st} active pattern 210 and the 2^{nd} active pattern 220 may have a width in the D2 direction which varies along the D1 direction. For example, as shown in FIG. 2A, the two active patterns 210 and 220 may have respectively and independently varying widths such that at least a portion of the 1^{st} active pattern 210 and at least a portion of the 2^{nd} active pattern 220 vertically thereabove may have a same width and vertically overlap in their entireties while the other portions of the 1^{st} active pattern 210 and the other portions of the 2^{nd} active pattern 220 vertically thereabove may not have same widths, respectively, and may vertically overlap only partially.

Further, the width of at least one of the 1^{st} active pattern 210 and the 2^{nd} active pattern 220 may vary non-linearly along the D1 direction. FIG. 2A shows that the 1^{st} active pattern 210 and the 2^{nd} active pattern 220 may both have non-linearly varying widths along the 1^{st} direction. Still, however, an average width of the 2^{nd} active pattern 220 may be smaller than that of the 1^{st} active pattern 210.

Moreover, in the multi-stack semiconductor device 20, a plurality of single diffusion break (SDB) structures 260 may be formed at positions where some of the gate structures 250 are to be formed or were formed, respectively, to isolate one or more multi-stack FETs therebetween from other multi-stack FETs or circuit elements adjacent thereto along the D1 direction. For example, a 2^{nd} multi-stack FET 20B shown in FIG. 2C may be isolated from a left-side 1^{st} multi-stack FET 20A shown in FIG. 2B and right-side source/drain regions by respective SDB structures 260. The SDB structures 260 may be formed of an isolation material such as silicon oxide (e.g., SiO₂), silicon nitride (e.g., Si₃N₄), polysilicon, or the like.

These SDB structures 260 may replace the active patterns 210 and 220 at their width-changing portions to be surrounded or surrounded by the corresponding gate structures 250. The SDB structures 260 may be formed at positions of the gate structures 250 surrounding the active patterns 210 and 220 at their width-changing portions because these gate structure 250 surrounding the width-changing portions of the active patterns 210 and 220 as channel structures may have undesirably changing gate threshold voltages. Thus, if an SDB structure is to be formed to replace portions of the active patterns 210 and 220 to isolate a multi-stack FET such as the 2^{nd} multi-stack FET 20B, this SDB structure may be formed at a position of a gate structure surrounding width-changing portions of the active patterns 210 and 220.

As the SDB structures 260 replace the width-changing portions of the active patterns 210 and 220 as channel structures, widths of the active patterns 210 and 220, for example, source/drain regions 213 and 223 at a left side and a right side of an SDB structure 260 may be different from each other. In contrast, widths of the active patterns 210 and 220, for example, source/drain regions 213 and 223 at a left side and a right side of a gate structure 250 may be equal.

It is to be understood here that the width-changing portions of the active patterns 210 and 220 are shown as being surrounded by or formed under the SDB structure 260 in FIG. 2A. However, this is only to show where the SDB structures 260 are formed in the multi-stack semiconductor device 20 although, in reality, these width-changing portions of the active patterns 210 and 220 are removed and replaced by the corresponding SDB structures 260.

Thus, the multi-stack semiconductor device 20 may be able to implement a plurality of multi-stack FETs having various, different dimensions and device performances along the D1 direction.

Referring to FIGS. 2A and 2B, a 1^{st} multi-stack FET 20A may include a 1^{st} FET formed of a 1^{st} channel structure 212, a 1^{st} source/drain region 213 and a gate structure 250, and a 2^{nd} FET formed of a 2^{nd} channel structure 222, a 2^{nd} source/drain region 223 and the gate structure 250. The 1^{st} multi-stack FET 20A may also include a backside isolation structure 201, a BDI layer 205 and a middle isolation layer 215.

The multi-stack FET 20A may be characterized in that the 1^{st} channel structure 212 of the 1^{st} FET and the 2^{nd} channel structure 222 of the 2^{nd} FET may have a same channel width W3 while the 2^{nd} channel structure 222 may still be formed of more channel layers than the 1^{st} channel structure 312. Thus, the 2^{nd} channel structure 222 may provide a greater effective channel width than the 1^{st} channel structure 212. Here, as the 2^{nd} FET including the 2^{nd} channel structure 222 is a PFET and has more channel layers than the 1^{st} FET which, as an NFET, includes the 1^{st} channel structure 212, the 1^{st} multi-stack FET 20A may form a NOR circuit which requires an improved DC performance for a PFET and reduced capacitance and current leakage for an NFET.

Referring to FIGS. 2A and 2C, a multi-stack FET 20B may include structural elements corresponding or similar to those of the 1^{st} multi-stack FET 20A, and thus, the same reference characters and numerals are used.

Unlike in the multi-stack FET 20A but similar to the multi-stack FET 10A of FIG. 1B, the multi-stack FET 20B may include a 2^{nd} channel structure 222 for a 2^{nd} FET having a smaller channel width than a 1^{st} channel structure 212 for a 1^{st} FET while the 2^{nd} channel structure 222 may still be formed of more channel layers than the 1^{st} channel structure 212. Further, in the multi-stack FET 20B, the 1^{st} channel structure 212 may be partially overlapped by the 2^{nd} channel structure 222 in the same manner as in the multi-stack FET 10A.

However, the 1^{st} channel structure 212 and the 2^{nd} channel structure 222 of the multi-stack FET 20B may have respective channel widths W3 and W4 which are smaller than the channel widths W1 and W2 of the 1^{st} channel structure 112 and the 2^{nd} channel structures 122 of the multi-stack FET 10A of FIG. 1B. Thus, compared to the multi-stack FET 10A, the multi-stack FET 20B may provide smaller effective channel widths. Moreover, a channel-width ratio W4/W3 in the multi-stack FET 20B is smaller than a channel-width ratio W2/W1 in the multi-stack FET 20A, an effective channel width of the 1^{st} channel structure 212 for the 1^{st} FET as NFET may be greater than an effective channel width of the 2^{nd} channel structure 222 of the 2^{nd} FET as PFET in the multi-stack FET 20B.

Accordingly, in a case where the multi-stack semiconductor device 20 implements, for example, a flip-flop circuit, the multi-stack FET 20B may form a NAND circuit which requires reduced capacitance and current leakage at a PFET and an improved DC performance at an NFET while the multi-stack FET 20A forms a NOR circuit. Further, as described in reference to FIGS. 1A and 1B, the multi-stack FET 20B may take advantages of the smaller-width 2^{nd} channel structure 222 in forming a frontside contact structure formed on a top surface of a 1^{st} source/drain region 213 not vertically overlapped by a 2^{nd} source/drain region 223.

Referring to FIGS. 2A and 2D, a multi-stack FET 20C may include structural elements corresponding or similar to those of the 1^{st} multi-stack FET 20B, and thus, the same reference characters and numerals are used.

Similar to the multi-stack FET 20B, the multi-stack FET 20C may also include a 1^{st} channel structure 212 and a 2^{nd} channel structure 222 having the respective channel widths W3 and W4 smaller than W3 while the 2^{nd} channel structure 222 may still be formed of more channel layers than the 1^{st} channel structure 212.

However, the 1^{st} channel structure 212 in the multi-stack FET 20C may be vertically overlapped by the 2^{nd} channel structure 222 in a manner different from that in the multi-stack FET 20B. In the multi-stack FET 20C, a non-overlapped free space through which a frontside contact structure can be formed may be provided at both sides of 2^{nd} source/drain regions 223 in the D2 direction. Thus, the multi-stack FET 20C may provide a more flexible design choice for BEOL structures including a frontside contact structure to be formed on a 1^{st} source/drain region 213 epitaxially grown from the 1^{st} channel structure 212 when the multi-stack FET 20C forms a NAND circuit.

Moreover, as a gate-cut structure is formed at each side of the multi-stack FET 20C, for example, at a left side and a right side of the channel structures 212 and 222 in the D2-direction view, that is, FIG. 2D, the gate structure surrounding 250 the 2^{nd} channel structure 222 of the multi-stack FET 20C may provide a more stable and consistent gate threshold voltage to the 2^{nd} channel structure 222 than the multi-stack FET 20B. This is because the 2^{nd} channel structures 222 is centered on the 1^{st} channel structure 212 in the multi-stack FET 20C while the 2^{nd} channel structure 222 is left-sided or shifter to the left on the 1^{st} channel structure 212 in the multi-stack FET 20B.

Referring to FIGS. 2A and 2E, a multi-stack FET 20D may include structural elements corresponding or similar to those of the 1^{st} multi-stack FET 20C, and thus, the same reference characters and numerals are used.

The multi-stack FET 20D may be the same as or similar to the multi-stack FET 10A of FIG. 1B in terms of a channel width W1 of a 1^{st} channel structures 212 and a channel width W2 of a 2^{nd} channel structure 222. Thus, the 1^{st} channel structure 212 and the 2^{nd} channel structure 222 in the multi-stack FET 20D may provide a same or a substantially same effective channel width so that the multi-stack FET 20D may be used as a CMOS device requiring a same effective channel width for a 1^{st} FET as NFET and a 2^{nd} FET as PFET.

Referring to FIGS. 2A and 2F, a multi-stack FET 20E may include structural elements corresponding or similar to those of the 1^{st} multi-stack FET 20D, and thus, the same reference characters and numerals are used.

The multi-stack FET 20E may be the same as the multi-stack FET 20D in terms of channel widths and channel-layer numbers. Thus, the 1^{st} channel structure 212 and the 2^{nd} channel structure 222 in the multi-stack FET 20E may provide a same or a substantially same effective channel width so that the multi-stack FET 20D may also be used as a CMOS device requiring a same effective channel width for a 1^{st} FET as NFET and a 2^{nd} FET as PFET.

However, the multi-stack FET 20E has a same or similar channel-structure overlapping pattern as the multi-stack FET 20C of FIG. 2D. Thus, the multi-stack FET 20E may also provide a more flexible design choice for BEOL structures including a frontside contact structure to be formed on a 1^{st} source/drain region 213 epitaxially grown from the 1^{st} channel structure 212. Further, the multi-stack FET 20E may also provide a more stable and consistent gate threshold voltage to the 2^{nd} channel structure 222 than the multi-stack FET 20D.

In the above embodiments of the multi-stack semiconductor device 20 including the multi-stack FETs 20A-20E, the 2^{nd} FET as PFET is described as being formed of more channel layers than the 1^{st} FET as NFET, while the channel layers of the two FETs have a same thickness in the D3 direction and a same length in the D1 direction. However, the disclosure may not be limited thereto. In the following embodiments of a multi-stack semiconductor device, a 1^{st} FET as PFET may be formed of more channel layers than a 2^{nd} FET as NFET.

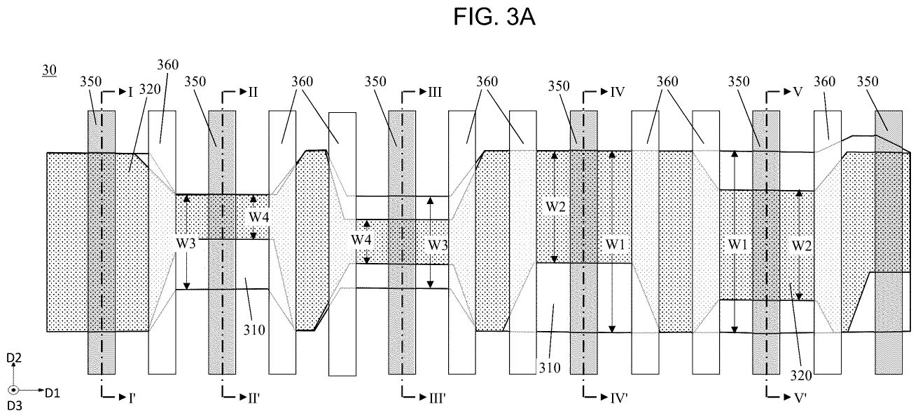

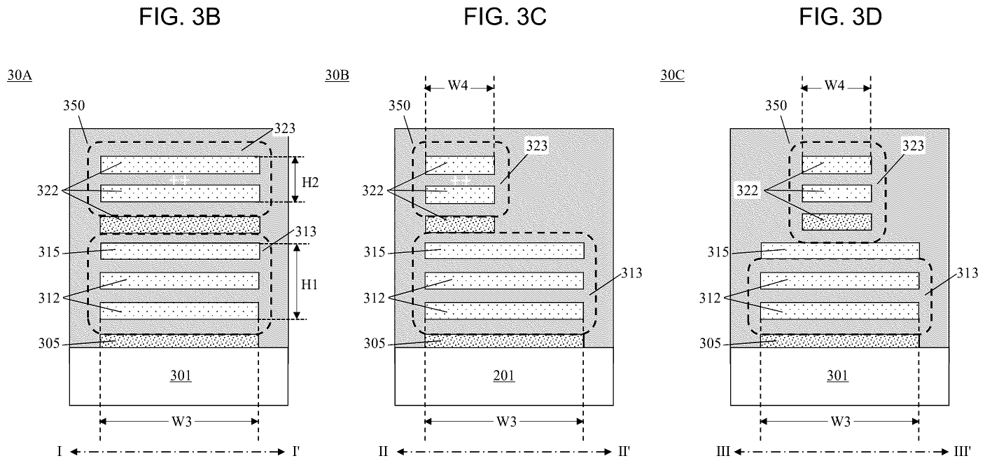

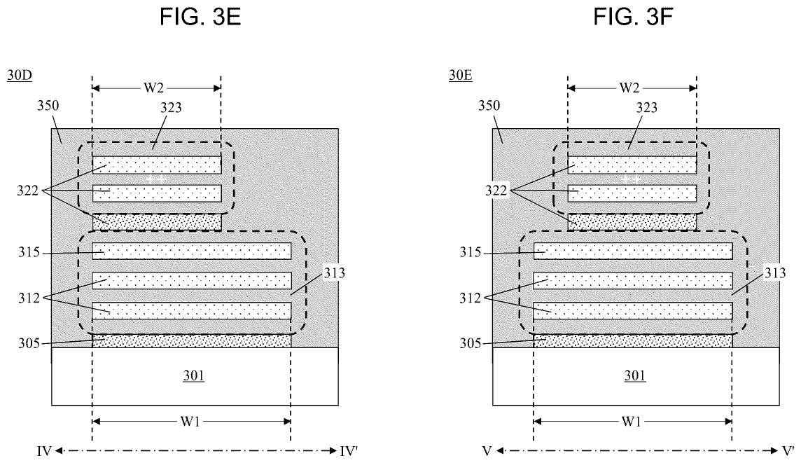

FIGS. 3A-3F illustrate a multi-stack semiconductor device in which a plurality of 1^{st} FETs at a 1^{st} level has varying channel widths and a plurality of 2^{nd} FETs at a 2^{nd} level also has varying channel widths, different from the varying channel widths of the 1^{st} FETs, the 1^{st} FET having less channel layers than the 2^{nd} FET, according to one or more other embodiments.

FIG. 3A, which may be the same as FIG. 2A, is a plan view of a multi-stack semiconductor device 30, and FIG. 3B-3F are cross-section views of the multi-stack semiconductor device 30 taken along lines I-I′, II-II′, III-III′, IV-IV′ and V-V′ shown in FIG. 3A. In order to assist better understanding of the multi-stack semiconductor device 30 of FIG. 3A, FIGS, 3B-3F also show source/drain regions that can be seen at different cross-section views using dashed lines.

Referring to FIG. 3A, like the multi-stack semiconductor device 20 of FIG. 2A, a multi-stack semiconductor device 30 may also include a 1^{st} active pattern 310 and a 2^{nd} active pattern 320 extending in the D1 direction having independently and respectively varying widths in the same manner in the multi-stack semiconductor device 20, while the 2^{nd} active pattern 320 is stacked on the 1^{st} active pattern 310 formed on a backside isolation structure 301 in the D3 direction. Thus, the multi-stack semiconductor device 30 may also be able to implement a plurality of multi-stack FETs having various, different dimensions and device performances along the D1 direction.

Also, like in the multi-stack semiconductor device 20, a plurality of gate structures 350 may be arranged in the D1 direction and may extend in the D2 direction across the active patterns 310 and 320. Further, a plurality of channel structures and source/drain regions may also be formed based on the active patterns 310 and 320 in the multi-stack semiconductor device 30 to form a plurality of multi-stack FETs each including a 1^{st} FET at the 1^{st} level and a 2^{nd} FET at the 2^{nd} level as in the multi-stack semiconductor device 20.

Furthermore, the multi-stack semiconductor device 30 may also include a plurality of SDB structures 360 corresponding to the SDB structure 260 shown in FIG. 2A.

Thus, duplicate descriptions thereof may be omitted herein.

However, unlike in the multi-stack semiconductor device 20, the 2^{nd} FETs may have more channel layers than the 1^{st} FETs, as shown in FIGS. 3B-3F, and the 1^{st} FETs may each be a PFET while the 2^{nd} FETs may each be of NFET in the multi-stack semiconductor device 30. This may be a structural configuration opposite to that of the multi-stack semiconductor device 20. Channel thicknesses and lengths in the multi-stack semiconductor device 30 may be the same as those in the multi-stack semiconductor device 20.

In this regard, duplicate descriptions about the channel structures, source/drain regions and gate structures for the 1^{st} FETs and the 2^{nd} FETs in terms of their functions and materials may be omitted, and instead, different aspects of the multi-stack semiconductor device 30 may be described herebelow.

Referring to FIGS. 3A and 3B, a 1^{st} multi-stack FET 30A may include a 1^{st} FET formed of a 1^{st} channel structure 312, a 1^{st} source/drain region 313 and a gate structure 350, and a 2^{nd} FET formed of a 2^{nd} channel structure 322, a 2^{nd} source/drain region 323 and the gate structure 350. The 1^{st} multi-stack FET 30A may also include a backside isolation structure 301, a BDI layer 205 and a middle isolation layer 215.

Like the multi-stack FET 20A of FIG. 2B, the multi-stack FET 30A may be characterized in that the 1^{st} channel structure 312 of the 1^{st} FET and the 2^{nd} channel structure 322 of the 2^{nd} FET may have a same channel width W3. However, unlike the multi-stack FET 20A, the multi-stack FET 30A may be structured such that the 1^{st} channel structure 312 is formed of more channel layers than the 2^{nd} channel structure 322 and a height H1 of the 1^{st} channel structure 312 may be greater than a height H2 of the 2^{nd} channel structure 322. Still, however, as the 2^{nd} channel structure 322 forming the 2^{nd} FET as NFET may provide a great effective channel width due to the enlarged width, the 1^{st} multi-stack FET 30A may form a NAND circuit which requires an improved DC performance for an NFET.

Referring to FIGS. 3A and 3C, a multi-stack FET 30B may include structural elements corresponding or similar to those of the 1^{st} multi-stack FET 30A, and thus, the same reference characters and numerals are used.

Like in the multi-stack FET 20B of FIG. 2C, the multi-stack FET 30B may include a 1^{st} channel structure 312 for a 1^{st} FET and a 2^{nd} channel structure 322 for a 2^{nd} FET having respective channel widths W3 and W4 smaller than W3, and further, the 1^{st} channel structure 312 may be partially overlapped by the 2^{nd} channel structure 322 in the same manner as in the multi-stack FET 20B.

However, unlike the multi-stack FET 20B, the multi-stack FET 30B may be structured such that the 1^{st} channel structure 312 of the 1^{st} FET, which is a PFET, is formed of more channel layers than the 2^{nd} channel structure 322 of the 2^{nd} FET, which is an NFET, and the 1^{st} channel structure 312 may have a greater height than the 2^{nd} channel structure 322. Thus, the multi-stack FET 30B may provide a smaller effective channel width for the NFET than the PFET.

Accordingly, in a case where the multi-stack semiconductor device 30 implements, for example, a flip-flop circuit, the multi-stack FET 30B may form a NOR circuit which requires reduced capacitance and current leakage for an NFET and an improved DC performance for a PFET while the multi-stack FET 30A forms a NAND circuit. The multi-stack FET 30B may also take advantages of the smaller-width 2^{nd} channel structure 322 in forming a frontside contact structure formed on a top surface of a 1^{st} source/drain region 313 not vertically overlapped by a 2^{nd} source/drain region 323.

Referring to FIGS. 3A and 3D, a multi-stack FET 30C may include structural elements corresponding or similar to those of the 1^{st} multi-stack FET 30B, and thus, the same reference characters and numerals are used.

Like the multi-stack FET 30B, the multi-stack FET 30C may also include a 1^{st} channel structure 312 and a 2^{nd} channel structure 322 having the respective channel widths W3 and W4 smaller than W3 while the 1^{st} channel structure 312 may still be formed of more channel layers than the 2^{nd} channel structure 322 and the 1^{st} channel structure 312 may have a greater height than the 2^{nd} channel structure 322. Further, the 1^{st} channel structure 312 may be vertically overlapped by the 2^{nd} channel structure 322 in the same manner in the multi-stack FET 20C of FIG. 2D. Thus, compared to the multi-stack FET 30B, the multi-stack FET 30C may provide a more flexible design choice for BEOL structures including a frontside contact structure to be formed on a 1^{st} source/drain region 313 epitaxially grown from the 1^{st} channel structure 312 when the multi-stack FET 30C forms a NOR circuit. Furthermore, like the multi-stack FET 20C, the multi-stack FET 30C may provide a more stable and consistent gate threshold voltage to the 2^{nd} channel structure 222 than the multi-stack FET 30B.

Referring to FIGS. 3A and 3E, a multi-stack FET 30D may include structural elements corresponding or similar to those of the 1^{st} multi-stack FET 30C, and thus, the same reference characters and numerals are used.

The multi-stack FET 30D may be the same as or similar to the multi-stack FET 30B of FIG. 3C in terms of channel width difference and channel-structure overlapping pattern. However, the channel structures 312 and 322 of the multi-stack FET 30D may each provide a greater effective channel width than the channel structures 312 and 322 of the multi-stack FET 30B. Thus, the multi-stack FET 30D may be used as a CMOS device requiring a greater power than the multi-stack FET 30B.

Referring to FIGS. 3A and 3F, a multi-stack FET 30E may include structural elements corresponding or similar to those of the 1^{st} multi-stack FET 20D, and thus, the same reference characters and numerals are used.

The multi-stack FET 30E may be the same as or similar to the multi-stack FET 30C of FIG. 3D in terms of a channel width difference and a channel-structure overlapping pattern. Thus, the multi-stack FET 30E may also provide a more flexible design choice for BEOL structures including a frontside contact structure to be formed on a 1^{st} source/drain region 313 epitaxially grown from the 1^{st} channel structure 312. Further, the multi-stack FET 30E may provide a more stable and consistent gate threshold voltage to the 2^{nd} channel structure 222 than the multi-stack FET 30D.

However, the channel structures 312 and 322 of the multi-stack FET 30E may each provide a greater effective channel width than the channel structures 312 and 322 of the multi-stack FET 30C. Thus, the multi-stack FET 30E may be used as a CMOS device requiring a greater power than the multi-stack FET 30C.

In the above embodiments of the multi-stack FETs 20A-20E and 30A-30E, the channel structures 212, 222, 312 and 322 are described as having two (2) or three (3) channel layers. However, these numbers of the channel layers are only examples, and the channel structures 212, 222, 312 and 322 may be formed of more or less than two (2) or three (3) channel layers as long as the 1^{st} FET has more channel layers than the 2^{nd} FET in the multi-stack FETs 20A-20E and the 1^{st} FET has less channel layers than the 2^{nd} FET in the multi-stack FETs 30A-30E, according to one or more other embodiments.

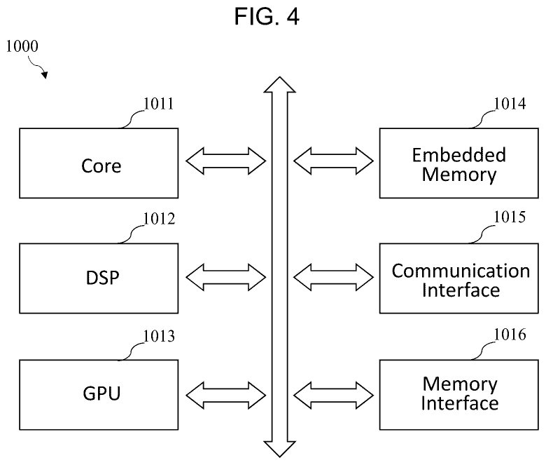

FIG. 4 is a schematic block diagram illustrating an electronic device including one or more multi-stack FETs including a plurality of different channel widths, according to one or more embodiments. The electronic device of FIG. 4 may include one or more of the multi-stack FETs 20B-20F and the multi-stack FETs 30B-30F.

Referring to FIG. 4, an SoC 1000 may be an integrated circuit in which components of a computing system or other electronic systems are integrated. As an example of the SoC 1000, an application processor (AP) may include at least one processor and components for various functions. The SoC 1000 may include a core 1011 (e.g., a processor), a digital signal processor (DSP) 1012, a graphic processing unit (GPU) 1013, an embedded memory 1014, a communication interface 1015, and a memory interface 1016. The components of the SoC 1000 may communicate with each other through a bus 1007.

The core 1011 may process instructions and control operations of the components included in the SoC 1000. For example, the core 1011 may process a series of instructions to run an operating system and execute applications on the operating system. The DSP 1012 may generate useful data by processing digital signals (e.g., a digital signal provided from the communication interface 1015). The GPU 1013 may generate data for an image output by a display device from image data provided from the embedded memory 1014 or the memory interface 1016, or may encode the image data.

The embedded memory 1014 may store data necessary for the core 1011, the DSP 1012, and the GPU 1013 to operate. The communication interface 1015 may provide an interface for a communication network or one-to-one communication. The memory interface 1016 may provide an interface for an external memory of the SoC 1000, such as a dynamic random access memory (DRAM), a flash memory, etc.

At least one of the core 1011, the DSP 1012, the GPU 1013, and/or the embedded memory 1014 may include one or more of the multi-stack FETs 20B-20F and the multi-stack FETs 30B-30F.

The foregoing is illustrative of example embodiments and is not to be construed as limiting the disclosure. Although a few example embodiments have been described, those skilled in the art will readily appreciate that many modifications are possible in the above embodiments without materially departing from the disclosure.

What is claimed is:

1. A multi-stack semiconductor device comprising:
a 1^{st} active pattern extending in a 1^{st} direction;
a 2^{nd} active pattern extending in the 1^{st} direction, the 2^{nd} active pattern being above the 1^{st} active pattern in a 3^{rd} direction which intersects the 1^{st} direction and a 2^{nd} direction intersecting the 1^{st} direction; and
a plurality of gate structures extending in the 2^{nd} direction across the 1^{st} active pattern and the 2^{nd} active pattern and arranged in the 1^{st} direction,
wherein at least one of the 1^{st} active pattern and the 2^{nd} active pattern has a width in the 2^{nd} direction which varies along the 1^{st} direction.

2. The multi-stack semiconductor device of claim 1,
wherein the 1^{st} active pattern comprises a plurality of channel structures on which the plurality of gate structures is formed, respectively, and
wherein the plurality of channel structures has different widths in the 2^{nd} direction.

3. The multi-stack semiconductor device of claim 1,
wherein the 1^{st} active pattern has a 1^{st} width which varies along the 1^{st} direction, and
wherein the 2^{nd} active pattern has a 2^{nd} width which varies along the 1^{st} direction.

4. The multi-stack semiconductor device of claim 3,
wherein at least one of the 1^{st} width and the 2^{nd} width varies non-linearly along the 1^{st} direction.

5. The multi-stack semiconductor device of claim 3,
wherein the 1^{st} active pattern comprises a plurality of 1^{st} channel structures on which the plurality of gate structures is formed, respectively,
wherein the plurality of 1^{st} channel structures has different widths in the 2^{nd} direction,
wherein the 2^{nd} active pattern comprises a plurality of 2^{nd} channel structures on which the plurality of gate structures is formed, respectively, and
wherein the plurality of 2^{nd} channel structures has different widths in the 2^{nd} direction.

6. The multi-stack semiconductor device of claim 5,
wherein at least one of the 2^{nd} channel structures has a smaller width than at least one of the 1^{st} channel structures below in the 3^{rd} direction.

7. The multi-stack semiconductor device of claim 6,
wherein at least another one of the 2^{nd} channel structures has a same width as at least another one of the 1^{st} channel structures below in the 3^{rd} direction.

8. The multi-stack semiconductor device of claim 1,
wherein the 1^{st} active pattern comprises a plurality of 1^{st} channel structures on which the plurality of gate structures is formed, respectively,
wherein the 2^{nd} active pattern comprises a plurality of 2^{nd} channel structures on which the plurality of gate structures is formed, respectively, and
wherein a 1^{st} channel structure among the plurality of 1^{st} channel structures has more channel layers than a 2^{nd} channel structure among the plurality of 2^{nd} channel structures, the 2^{nd} channel structure being above the 1^{st} channel structure in the 3^{rd} direction.

9. The multi-stack semiconductor device of claim 8,
wherein the 2^{nd} channel structure has a smaller width than the 1^{st} channel structure.

10. The multi-stack semiconductor device of claim 9,
wherein the 1^{st} channel structure forms an n-type field-effect transistor (NFET), and
wherein the 2^{nd} channel structure forms a p-type field-effect transistor (PFET).

11. The multi-stack semiconductor device of claim 10,
wherein a multi-stack field-effect transistor comprising the NFET and the PFET forms a NAND circuit.

12. The multi-stack semiconductor device of claim 1,
wherein the 1^{st} active pattern comprises a plurality of 1^{st} channel structures on which the plurality of gate structures is formed, respectively,
wherein the 2^{nd} active pattern comprises a plurality of 2^{nd} channel structures on which the plurality of gate structures is formed, respectively, and
wherein a 1^{st} channel structure among the plurality of 1^{st} channel structures has less channel layers than a 2^{nd} channel structure among the plurality of 2^{nd} channel structures, the 2^{nd} channel structure above the 1^{st} channel structure in the 3^{rd} direction.

13. The multi-stack semiconductor device of claim 12,
wherein the 2^{nd} channel structure has a smaller width than the 1^{st} channel structure.

14. The multi-stack semiconductor device of claim 13,
wherein the 1^{st} channel structure forms a p-type field-effect transistor (PFET), and
wherein the 2^{nd} channel structure forms an n-type field-effect transistor (NFET).

15. The multi-stack semiconductor device of claim 14,
wherein a multi-stack field-effect transistor comprising the PFET and the NFET forms a NOR circuit.

16. The multi-stack semiconductor device of claim 1, further comprising:
at least one diffusion break structure extending in the 2^{nd} direction across the 1^{st} active pattern and the 2^{nd} active pattern,
wherein the at least one of the 1^{st} active pattern and the 2^{nd} active pattern has different widths in the 2^{nd} direction at a 1^{st} side and a 2^{nd} side, opposite to the 1^{st} side, of the at least one diffusion break structure along the 1^{st} direction.

17. A multi-stack semiconductor device comprising:
a 1^{st} channel structure comprising 1^{st} channel layers arranged in a 3^{rd} direction intersecting a 1^{st} direction and a 2^{nd} direction; and
a 2^{nd} channel structures above the 1^{st} channel structure, the 2^{nd} channel structure comprising 2^{nd} channel layers arranged in the 3^{rd} direction,
wherein the 2^{nd} channel structure has a smaller width than the 1^{st} channel structure in the 2^{nd} direction, and
wherein a number of the 1^{st} channel layers is greater than a number of the 2^{nd} channel layers.

18. The multi-stack semiconductor device of claim 17,
wherein the 1^{st} channel structure forms a p-type field-effect transistor (PFET), and
wherein the 2^{nd} channel structure forms an n-type field-effect transistor (NFET).

19. A semiconductor device comprising:
a 1^{st} active pattern extending in a 1^{st} direction;
a gate structure extending in a 2^{nd} direction across the 1^{st} active pattern, the 2^{nd} direction intersecting the 1^{st} direction; and
a 2^{nd} channel structure above the 1^{st} channel structure in a 3^{rd} direction intersecting a 1^{st} direction and a 2^{nd} direction,
wherein the 1^{st} channel structure has a greater height than the 2^{nd} channel structure.

20. The multi-stack semiconductor device of claim 19,
wherein the 1^{st} channel structure forms a p-type field-effect transistor (PFET), and
wherein the 2^{nd} channel structure forms an n-type field-effect transistor (NFET).
